(19) United States
(12) Patent Application Publication
(10) Pub. No.: US 2014/0097903 A1
(43) Pub. Date: Apr. 10, 2014

(54) DOHERTY AMPLIFIER

(71) Applicant: FUJITSU LIMITED, Kawasaki-shi (JP)

(72) Inventors: Nobuhisa AOKI, Kawasaki (JP); Michiharu NAKAMURA, Yokosuka (JP)

(73) Assignee: FUJITSU LIMITED, Kawasaki-shi (JP)

(21) Appl. No.: 14/017,452

(22) Filed: Sep. 4, 2013

(30) Foreign Application Priority Data
Oct. 4, 2012 (JP) 2012-222554

(51) Int. Cl. H03F 3/68

(52) U.S. Cl. CPC H03F 3/68
USPC 330/295

(57) ABSTRACT

A Doherty amplifier comprises a first amplifier, one or more second amplifiers and a third amplifier to receive inputs of high-frequency signals in parallel, wherein the first amplifier serving as a carrier amplifier amplifies the high-frequency signal, each of the second amplifiers serving as the carrier amplifiers or peaking amplifiers amplifies the high-frequency signal, and the third amplifier serving as the peaking amplifier amplifies the high-frequency signal.

### CROSS-REFERENCE TO RELATED APPLICATION

This application is based upon and claims the benefit of priority of the prior Japanese Patent Application No. 2012-222554 filed on Oct. 4, 2012, the entire contents of which are incorporated herein by reference.

### FIELD

The present invention relates to a Doherty amplifier.

### BACKGROUND

In a wireless communication system, high-frequency carriers spreading over broad bandwidths are amplified by the same type of high output/power amplifiers.

In the high frequency amplifier, instantaneous output power and a distribution of frequency with respect to the instantaneous output power change as the case may be if an input signal modulation method and a signal multiplexing method are changed. In a Doherty amplifier, efficiency has maximum points at a maximum output voltage and an intermediate output voltage, the voltage at the maximum point of the intermediate efficiency is controlled to maximize the efficiency when a modulation signal is inputted on the basis of the instantaneous output power of the modulation signal and the frequency distribution.

FIG. 1 is a diagram illustrating an example of the efficiency against a standardized output voltage of the Doherty amplifier. The axis of abscissa of a graph in FIG. 1 indicates such a standardized output voltage that the maximum voltage to be output by the Doherty amplifier is standardized to “1”, and the axis of ordinate indicates the efficiency. In the example of FIG. 1, the efficiency of the Doherty amplifier has the maximum points at standardized output voltages of 0.5 and 1.

FIG. 2 is a diagram illustrating an example of a configuration of a conventional Doherty amplifier using plurality of devices. The Doherty amplifier includes a carrier amplifier (CA) and a peaking amplifier (PA). In FIG. 2, the Doherty amplifier includes one carrier and a plurality of peaking amplifiers. In the Doherty amplifier of FIG. 2, the single carrier amplifier and the plurality of peaking amplifiers PA are connected in parallel. Input signals are distributed. A part of distributed signals are inputted to the carrier amplifier. An output of the carrier amplifier is impedance-converted at a λ/4 line. The remaining distributed signals are rotated in phase through 90 degrees in the λ/4 line and then inputted to the peaking amplifiers. The impedance-converted output of the carrier amplifier and the outputs of the peaking amplifiers are synthesized. The synthesized signal is connected to an output load.

FIG. 3 is a diagram depicting an example of how the efficiency against the standardized output voltage of the Doherty amplifier differs depending on a ratio of the number of the carrier amplifier CA to the number of the peaking amplifiers PA (a ratio of a device size of CA to a device size of PA). The axis of abscissa of a graph in FIG. 3 indicates such a standardized output voltage that the maximum voltage to be output by the Doherty amplifier is standardized to “1”, and the axis of ordinate indicates the efficiency. As illustrated in FIG. 3, when the ratio of the number of CA to the number of PA changes, the voltage (the standardized output voltage) at the maximum point of the intermediate efficiency changes.

### DOCUMENTS OF PRIOR ARTS

### Patent Document

[Patent document 1] Japanese Unexamined Patent Publication No. 2003-536313
[Patent document 2] Japanese Patent Application Laid-Open Publication No. 2009-260658
[Patent document 3] Japanese Patent Application Laid-Open Publication No. 2010-34954
[Patent document 4] Japanese Patent Application Laid-Open Publication No. 2008-35487
[Patent document 5] Japanese Patent Application Laid-Open Publication No. 2006-165856

### Non-Patent Document

[Non-Patent document 1] B. Kim, I. Kim, J. Moon, “Advanced Doherty Architecture”, IEEE microwave magazine, pp. 72-86, August 2010.

### SUMMARY

The conventional Doherty amplifier using the plurality of devices has difficulty to change the voltage (standardized output voltage) at a maximum point of intermediate efficiency in a way that matches with instantaneous output power and a distribution of frequency with respect to the instantaneous output power for a plurality of communication systems that are different in terms of a modulation method and a signal multiplexing method. Further, it is difficult to change the voltage (standardized output voltage) at the maximum point of the intermediate efficiency in a way that matches with instantaneous output power. Hence, if the single Doherty amplifier is used for the plurality of communication systems with the modulation method and the signal multiplexing method being different, the amplifier exhibits the high efficiency for a certain communication system, and nevertheless it happens that the efficiency of the amplifier reduces for other communication systems. As a result, the efficiency of the amplifier decreases (on the whole). If the efficiency of the amplifier decreases, such a problem can arise that heat is emitted and power consumption rises. In the amplifier with no distortion, the output voltage is proportional to the input voltage.

According to an aspect of the disclosure, a Doherty amplifier includes a first amplifier, one or more second amplifiers and a third amplifier to receive inputs of high-frequency signals in parallel,

wherein the first amplifier serving as a carrier amplifier amplifies the high-frequency signal,

each of the second amplifiers serving as the carrier amplifiers or peaking amplifiers amplifies the high-frequency signal, and

the third amplifier serving as the peaking amplifier amplifies the high-frequency signal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a diagram illustrating an example of efficiency against standardized output voltage of a Doherty amplifier.

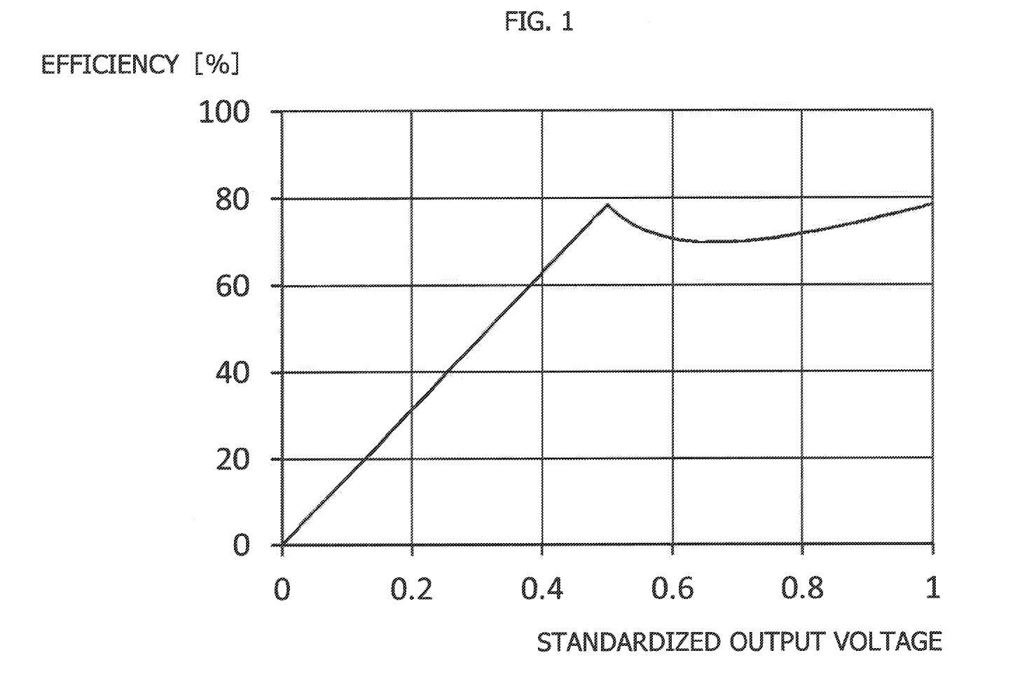

FIG. 2 is a diagram of a configuration of a conventional Doherty amplifier using a plurality of devices.

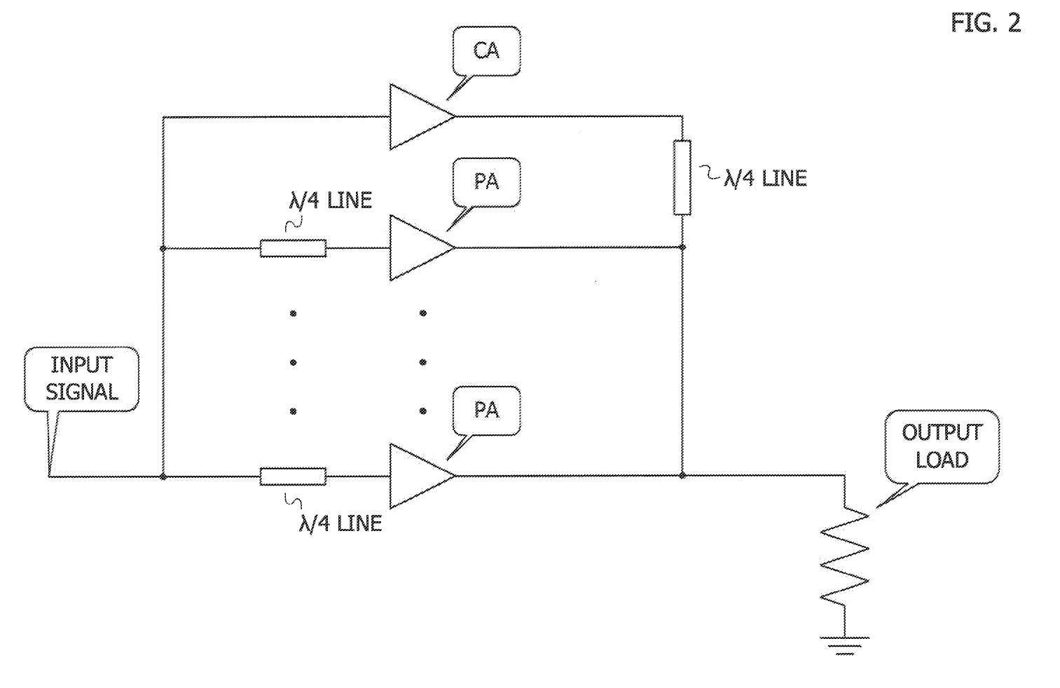

FIG. 3 is a diagram depicting an example of how the efficiency against the standardized output voltage of the Doherty amplifier differs depending on a ratio of the number of a carrier amplifier CA to the number of peaking amplifiers PA.

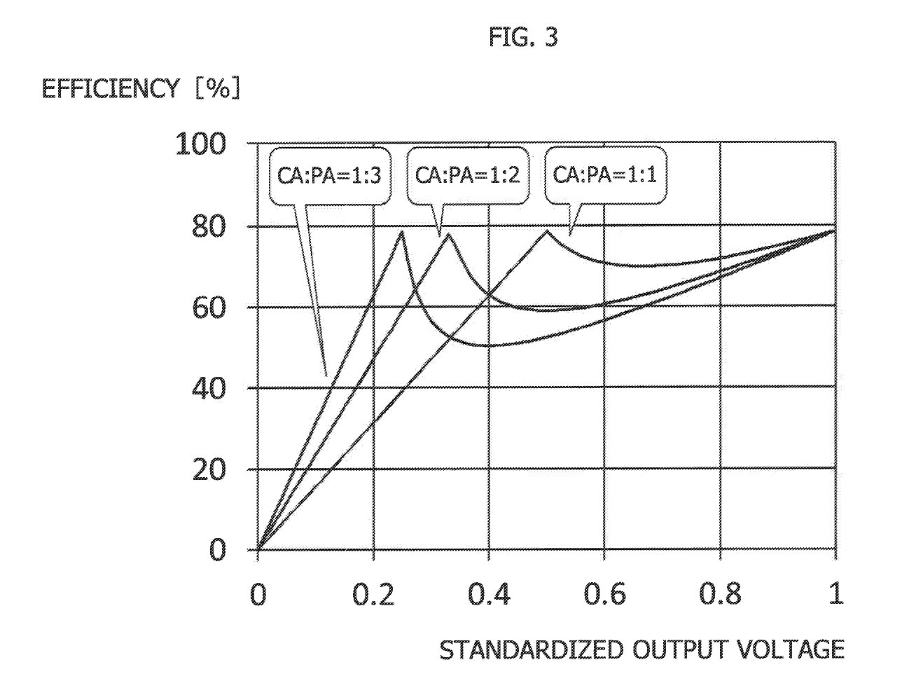

FIG. 4 is a diagram illustrating an example of the Doherty amplifier in a first embodiment.

FIG. 5 is a diagram illustrating examples of a ratio of a total of device sizes of the carrier amplifiers CA to a total of device sizes of the peaking amplifiers PA with respect to the efficiency against the output voltage that can be taken by a Doherty amplifier 100.

FIG. 6 is a diagram depicting an example of the Doherty amplifier in a modified example 1-1.

FIG. 7 is a diagram illustrating examples of the ratio of the total of the device sizes of the carrier amplifiers CA to the total of the device sizes of the peaking amplifiers PA with respect to the efficiency against the output voltage that can be taken by a Doherty amplifier 200.

FIG. 8 is a diagram depicting an example of the Doherty amplifier in a modified example 1-2.

FIG. 9 is a diagram depicting an example of the Doherty amplifier in a modified example 1-3.

FIG. 10 is a diagram illustrating an example of the Doherty amplifier in a second embodiment.

FIG. 11 is a diagram illustrating one example of a wireless device.

FIG. 12 is a diagram illustrating another example of the wireless device.

FIG. 13 is a diagram illustrating still another example of the wireless device.

FIG. 14 is a diagram illustrating an example of the Doherty amplifier in a third embodiment.

FIG. 15 is a diagram illustrating an example of a configuration of the wireless device including the Doherty amplifier.

### DESCRIPTION OF EMBODIMENTS

Embodiments will hereinafter be described with reference to the drawings. Configurations of the embodiments are exemplifications, and the configuration of the disclosure is not limited to the specific configurations of the embodiments of the disclosure. Implementation of the configuration of the disclosure may involve properly adopting the specific configurations corresponding to the embodiments.

The respective embodiments can be carried out in the way of their being combined to the greatest possible degree.

### First Embodiment

### Example of Configuration

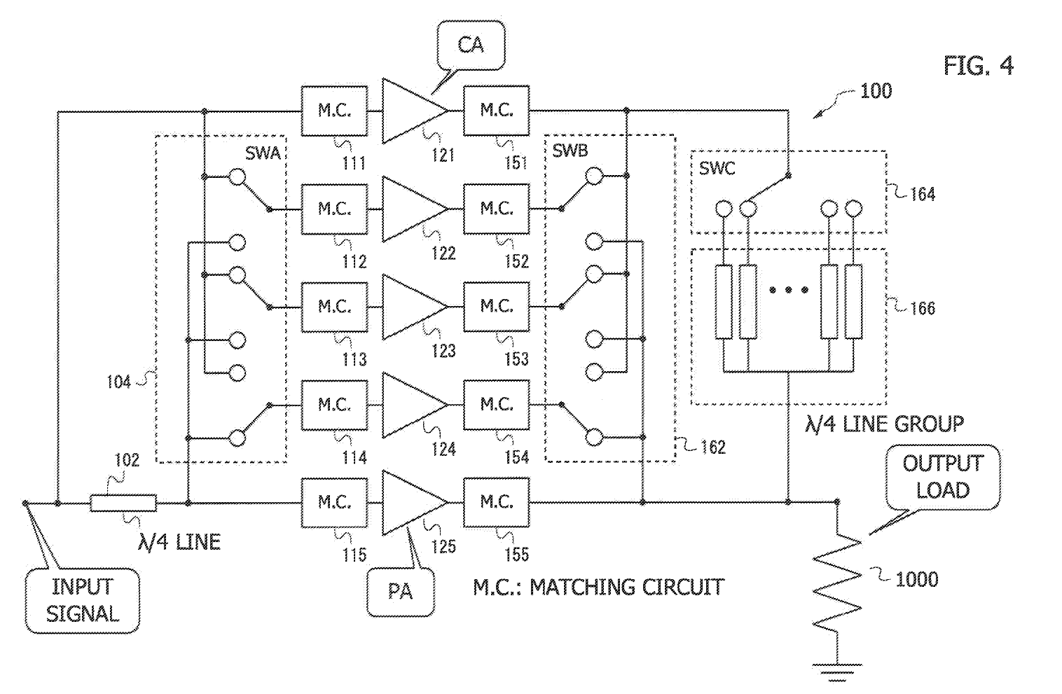

FIG. 4 is a diagram illustrating an example of a Doherty amplifier according to a first embodiment. A Doherty amplifier 100 includes a λ/4 line 102, an input-side switch A 104, a plurality of matching circuits 111-115 on an input side, a plurality of amplifiers 121-125, and a plurality of matching circuits 151-155 on an output side. The Doherty amplifier 100 further includes an output-side switch B 162, a switch C 164 and a λ/4 line group 166. Moreover, an output load 1000 is connected to the Doherty amplifier 100. The amplifier 121 operates as a carrier amplifier (CA). The amplifier 125 operates as a peaking amplifier (PA). An input signal is, e.g., an RF (Radio Frequency) signal. High frequency signals as the input signals are inputted in parallel to the amplifier serving as the carrier amplifier and to the amplifier serving as the peaking amplifier. The high frequency signal is inputted via the λ/4 line 102 to the amplifier as the peaking amplifier. The signals amplified by the respective amplifiers are synthesized and are thus output.

The λ/4 line (quarter-wave line) 102 having a line wave length that is ¼ as short as the frequency amplified by the Doherty amplifier, is provided on the line on the input side of the amplifier operating as the peaking amplifier and delays a phase of the signal by 90 degrees.

The input-side switch A 104 performs switchover about which amplifier, the carrier amplifier or the peaking amplifier, each of the amplifiers 122, 123 and 124 is operated as. The amplifier, which is made to connect with the output side of the λ/4 line 102 by the input-side switch A 104, operates as the peaking amplifier. The amplifier, which is made not to connect with the output side of the λ/4 line 102 by the input-side switch A 104, operates as the carrier amplifier. In the example of FIG. 4, the amplifiers 122 and 123 operate as the carrier amplifiers, while the amplifier 124 operates as the peaking amplifier. The input-side switch A 104 operates together with the output-side switch B 162.

The input-side matching circuits 111-115 take matching with the input sides of the amplifiers 121-125 connected thereto. For example, the matching circuit 111 takes matching with the input side of the amplifier 121 connected thereto.

The amplifier 121, to which the input signal is inputted via the matching circuit 111, operates as the carrier amplifier.

The amplifiers 122, 123 and 124 can operate also as the carrier amplifiers and the peaking amplifiers as well by dint of the switchover of the input-side switch A 104 and the switchover of the output-side switch B 162. Herein, there are the three amplifiers 122-124 enabled to operate as the carrier amplifiers and the peaking amplifiers as well, however, the number of these types of amplifiers is not limited to “3”. It may be sufficient that there are at least one or more amplifiers enabled to operate as the carrier amplifiers and the peaking amplifiers as well.

The amplifier 125 is connected to the output side of the λ/4 line 102 via the matching circuit 115 and operates as the peaking amplifier.

Device sizes of the amplifiers 121-125 may be the same and may also be different from each other. Herein, an assumption is that the device size of each of the amplifiers 122, 123 and 124 has a value “1”, while the device size of each of the amplifiers 121 and 125 has a value “4”. The device size of each amplifier is predetermined based on, e.g., a presumed input signal. At this time, the Doherty amplifier 100 can take four types of CA-to-PA ratios such as 4:7, 5:6, 6:5 and 7:4 (the CA-to-PA ratio (CA:PA) is a ratio of a total of the device sizes of the amplifiers operating as the carrier amplifiers (CA) to a total of the device sizes of the amplifiers operating as the peaking amplifiers (PA)).

The output-side matching circuits 151-155 take matching with the respective output sides of the amplifiers 121-125 connected thereto. For example, the matching circuit 151 takes matching with the output side of the amplifier 121 connected thereto. For instance, FETs (Field Effect Transistors) can be used as the amplifiers 121-125. A gate voltage for the CA is applied to the amplifier that can be employed as the carrier amplifier CA. Further, the gate voltage for the PA is applied to the amplifier that can be employed as the peaking amplifier PA. Transistors may also be used as the amplifiers 121-125.

The output-side switch B 162 operates together with the input-side switch A 104. The output-side switch B 162 gets the amplifier operating as the carrier amplifier to connect with the switch C 164. The output-side switch B 162 gets the amplifier operating as the peaking amplifier to connect with the output. The input-side switch A 104 and the output-side switch B 162 are given by way of one example of a switching unit.

The switch C 164 switches over the λ/4 line 102 for use on the basis of the number of the carrier amplifiers and the number of the peaking amplifiers. The switch C 164 operates together with the input-side switch A 104 and the output-side switch B 162. The ratio “CA:PA” of the Doherty amplifier 100 is changed by the input-side switch A 104 and the output-side switch B 162.

The λ/4 line group 166 includes the plurality of λ/4 lines, which are switched over by the switch C 164. The respective λ/4 lines have characteristic impedances different from each other. One λ/4 line is allocated per type of ratio “CA:PA”. The λ/4 line 102 and the λ/4 line of the λ/4 line group 166 synchronize the output of the carrier amplifier with the output of the peaking amplifier.

An output load 1000 is, e.g., an antenna. An impedance of the output load 1000 is notated by “R”. The signals amplified by the amplifiers as the carrier amplifiers are synthesized with the signals amplified by the amplifiers as the peaking amplifiers via the λ/4 lines of the λ/4 line group 166 and are output to the output load 1000.

A characteristic impedance R_{L} of each of the λ/4 lines of the λ/4 line group 166, which are switched over by the switch C 164, is obtained as follows.

$${R}_{L} = \frac{1 + m}{m} \cdot R \qquad [ Mathematical Expression 1 ]$$

Herein, the symbol “R” represents the impedance of the output load 1000. Further, the symbol “m” represents the ratio of the total of the device sizes of the carrier amplifiers CA to the total of the device sizes of the peaking amplifiers PA. It is herein assumed that, as described above, the device size of each of the amplifier 121 and 125 is “4”, while the device size of each of the amplifiers 122, 123 and 124 is “1”. The example in FIG. 4 is that the amplifiers 122, 123 and 124 operate as the carrier amplifiers, while the amplifiers 124 and 125 operate as the peaking amplifiers, and hence the ratio “m” becomes 6/5. The characteristic impedance R_{L} of the λ/4 line comes to R·11/6. Namely, at this time, the switch C 164 is connected to the λ/4 line, with its characteristic impedance R_{L} being R·11/6, of the λ/4 line group 166. For instance, as in the case of the Doherty amplifier 100, if there are the four types of ratios “m”, the λ/4 line group 166 includes the four types of λ/4 lines. The λ/4 line included in the λ/4 line group 166 is the λ/4 line having the characteristic impedance calculated in the following formula.

The input-side switch A 104, the output-side switch B 162 and the switch C 164 are switched over based on an input signal modulation method, a signal multiplexing method, etc. For example, the respective switches are switched over based on an associative table in which the modulation method, the signal multiplexing method, etc (communication systems) are associated with positions of the switches. The associative table between the modulation method, the signal multiplexing method, etc and the positions of the switches is predetermined. The associative table can be stored as, e.g., an associative table database in an unillustrated storage device. The device size ratio CA:PA of the Doherty amplifier 100 is predetermined corresponding to instantaneous power of each of the modulation methods and a distribution of frequency with respect to the instantaneous power. The electric power of the instantaneous power can be converted into a voltage. The voltage can be converted into a standardized voltage. In each communication system, what the frequency with respect to the instantaneous power is multiplied by efficiency of the standardized voltage corresponding to the instantaneous power is integrated by the standardized voltage from “0” to “1” per device size ratio CA:PA that can be taken by the Doherty amplifier 100, thereby obtaining the efficiency of the amplifier per device size ratio CA:PA. Namely, the efficiency of the Doherty amplifier 100 is obtained per communication system and per device size ratio CA:PA. Comparisons therebetween are made, whereby the most efficient device size ratio CA:PA is obtained per communication system.

Each of the switches involves using, e.g., an MEMS (Micro Electro Mechanical Systems) switch.

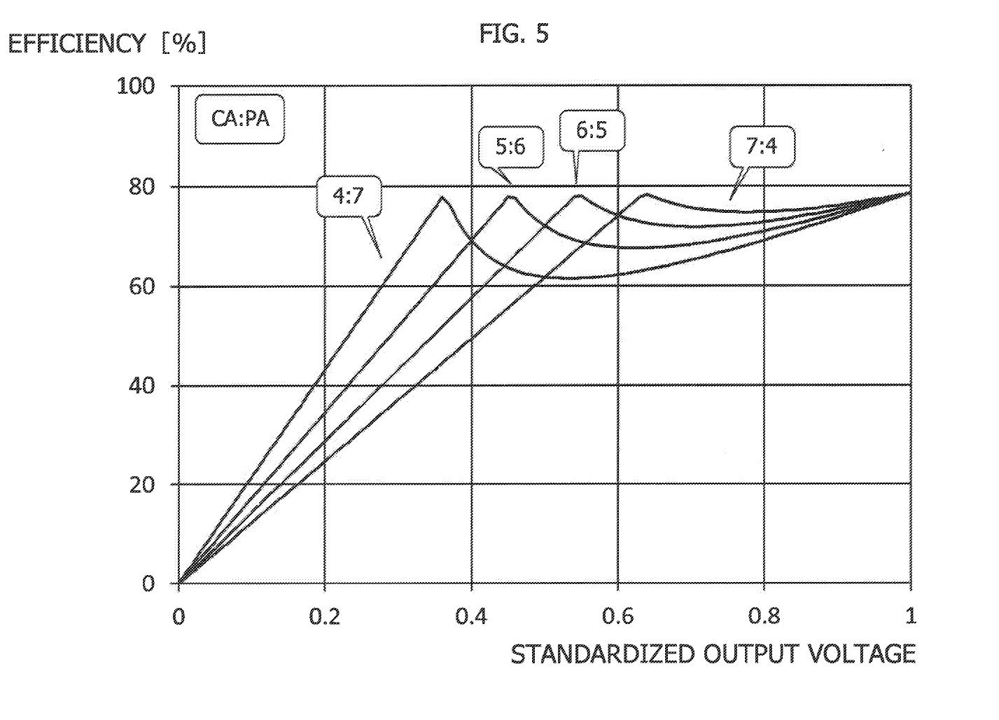

FIG. 5 is a diagram illustrating examples of the device size ratio CA:PA of the total of the device sizes of the carrier amplifiers CA to the total of the device sizes of the peaking amplifiers PA with respect to the efficiency against the output voltage that can be taken by the Doherty amplifier 100. The axis of abscissa of a graph in FIG. 5 indicates such a standardized output voltage that the maximum voltage to be output by Doherty amplifier 100 at each device size ratio CA:PA is standardized to “1”, and the axis of ordinate indicates the efficiency. As depicted in FIG. 5, the Doherty amplifier 100 can change the voltage (standardized output voltage) at the maximum point of intermediate efficiency by changing the ratio between CA and PA.

### Operation and Effect of First Embodiment

In the Doherty amplifier 100, the input-side switch A 104 and the output-side switch B 162 switch over the amplifiers 122-124 to the carrier amplifiers or the peaking amplifiers. The λ/4 lines of the λ/4 line group 166 are connected to the amplifiers operating as the carrier amplifiers. Each of the λ/4 lines connected to the amplifiers operating as the carrier amplifiers has the impedance based on the ratio of the total of the device sizes of the amplifiers operating as the carrier amplifiers to the total of the device sizes of the amplifiers operating as the peaking amplifiers.

The Doherty amplifier 100 includes the plurality of λ/4 lines, having the impedances different from each other, of the λ/4 line group 166 and is thereby enabled to acquire the proper output as the amplifier even when the device size ratio CA:PA is changed.

The Doherty amplifier 100 does not fix the device size ratio CA:PA. The Doherty amplifier 100 can change the output voltage (the standardized output voltage) under which the efficiency is maximized by changing the device size ratio CA:PA. The Doherty amplifier 100 can change the device size ratio PA:CA on the input signal modulation method etc and is thereby enabled to increase the efficiency of the amplifier for whichever modulation method.

The Doherty amplifier 100 can change the voltage (the standardized output voltage) at the maximum point of the intermediate efficiency in a way that matches with the instantaneous power of each modulation method and with the distribution of the frequency with respect to the instantaneous power.

Note that the device size of the amplifier corresponds, in the case of the FET as the amplifier, the number of gates and a gate width of the FET, and a magnitude of the electric current, which can flow to the device, is determined based on the device size. Further, a change in characteristic impedance of the λ/4 line can be attained by changing a line width of the λ/4 line.

### Modified Example 1-1

A modified example 1-1 of the first embodiment will be described. The discussion herein will be focused on different points from the Doherty amplifier 100 described above, while explanations of common points therebetween are omitted. In the modified example 1-1, the output-side switch B 162 can take three statuses.

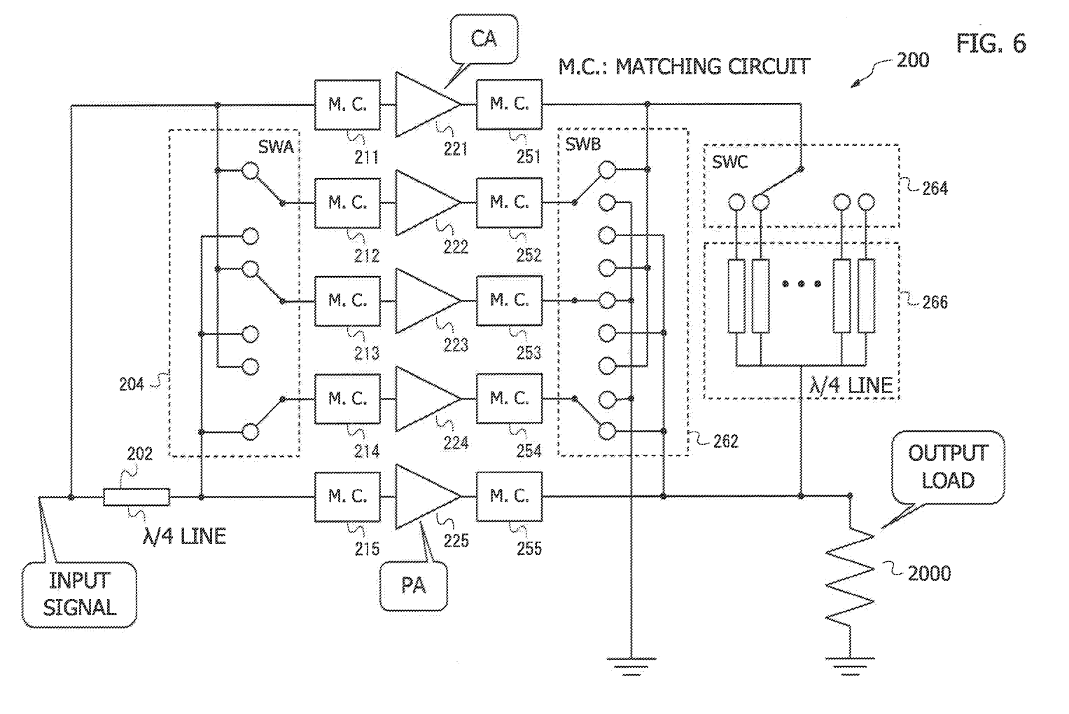

FIG. 6 is a diagram illustrating an example of the Doherty amplifier in the modified example 1-1 of the first embodiment. A Doherty amplifier 200 in FIG. 6 includes a λ/4 line 202, an input-side switch A 204, a plurality of matching circuits 211-215 on the input side, a plurality of amplifiers 221-225, and a plurality of matching circuits 251-255 on the output side. The Doherty amplifier 200 further includes an output-side switch B 262, a switch C 264 and a λ/4 line group 266. Moreover, an output load 2000 is connected to the Doherty amplifier 200. The λ/4 line 202, the input-side switch A 204, the plurality of matching circuits 211-215 on the input side, the plurality of amplifiers 221-225, and the plurality of matching circuits 251-255 on the output side are the same as the corresponding components of the Doherty amplifier 100.

The output-side switch B 262 operates together with the input-side switch A 204. The output-side switch B 262 gets the amplifier operating as the carrier amplifier to connect with the switch C 264. The output-side switch B 262 gets the amplifier operating as the peaking amplifier to connect with the output. If the amplifiers 222-224 are not operated as the amplifiers, however, the amplifiers 222-224 are earthed directly or through a proper load by the output-side switch B 262. Namely, the output-side switch B 262 switches over the amplifiers 222-224 to any one of three statuses such as a carrier amplifier status, a peaking amplifier status and a non-operating status. The output-side switch B 262 can perform the switchover of the three statuses. In the example of FIG. 6, the amplifier 222 operates as the carrier amplifier, the amplifier 223 is in the non-operating status, and the amplifier 224 operates as the peaking amplifier. The switch capable of switching over the three statuses may be provided in the input-side switch A 204. Herein, the amplifiers 222-224 switched over to one of the carrier amplifier status, the peaking amplifier status and the non-operating status are counted to be “3”, however, the number of these amplifiers is not limited to “3”. It is sufficient that the number of the amplifier(s) switched over to one of the carrier amplifier status, the peaking amplifier status and the non-operating status is equal to or more than at least “1”.

The device sizes of the amplifiers 221-225 may be the same and may also be different from each other. Herein, the assumption is that the device size of each of the amplifiers 222, 223 and 224 has the value “1”, while the device size of each of the amplifiers 221 and 225 has the value “4”. At this time, the Doherty amplifier 200 can take ten types of CA-to-PA ratios such as 4:4, 4:5, 4:6, 4:7, 5:4, 5:5, 5:6, 6:4, 6:5 and 7:4. The Doherty amplifier 200 using the same amplifiers as those of the Doherty amplifier 100 described above can take more multiple types of device size ratios CA:PA than the types of the device size ratio CA:PA of the Doherty amplifier 100.

The λ/4 line group 266 includes the plurality of λ/4 lines switched over by the switch C 264. The respective λ/4 lines have the characteristic impedances different from each other. The single λ/4 line is allocated per type of ratio of CA to PA.

The Doherty amplifier 200 herein uses the output-side switch B 262 capable of switching over the three statuses. In place of using the switch capable of switching over the three statuses, the Doherty amplifier 200 may be configured not to operate the amplifiers 222-224 as the amplifiers by controlling the voltage applied to the amplifiers 222-224. For example, if the amplifiers 222-224 are the FETs, the amplifiers 222-224 may not be operated as the amplifiers by changing gate voltages or drain voltages thereof. Moreover, if the amplifiers 222-224 are the transistors, the amplifiers 222-224 may not be operated as the amplifiers by changing base voltages or collector voltages thereof.

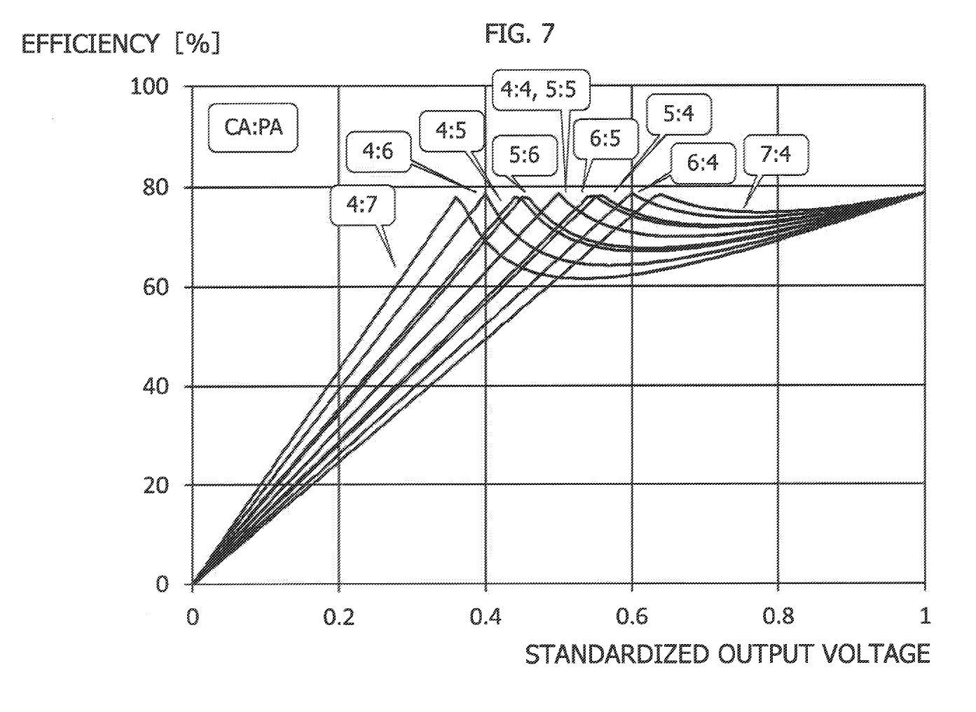

FIG. 7 is a diagram illustrating examples of the ratio of the total of the device sizes of the carrier amplifiers CA to the total of the device sizes of the peaking amplifiers PA with respect to the efficiency against the output voltage that can be taken by the Doherty amplifier 200. The axis of abscissa of a graph in FIG. 7 indicates such a standardized output voltage that the Doherty amplifier 200 standardizes the maximum voltage to be output at each device size ratio CA:PA to “1”, and the axis of ordinate indicates the efficiency. As depicted in FIG. 7, the Doherty amplifier 200 can change the voltage (standardized output voltage) at the maximum point of intermediate efficiency by changing the ratio between CA and PA. The Doherty amplifier 200 can take more multiple types of ratios (CA:PA) than in the case of the Doherty amplifier 100.

### Modified Example 1-2

A modified example 1-2 of the first embodiment will be described. The discussion herein will be focused on different points from the Doherty amplifier 100 or the Doherty amplifier 200 described above, while the explanations of the common points therebetween are omitted. In the modified example 1-2, a switching device is used as a substitute for the input-side switch A.

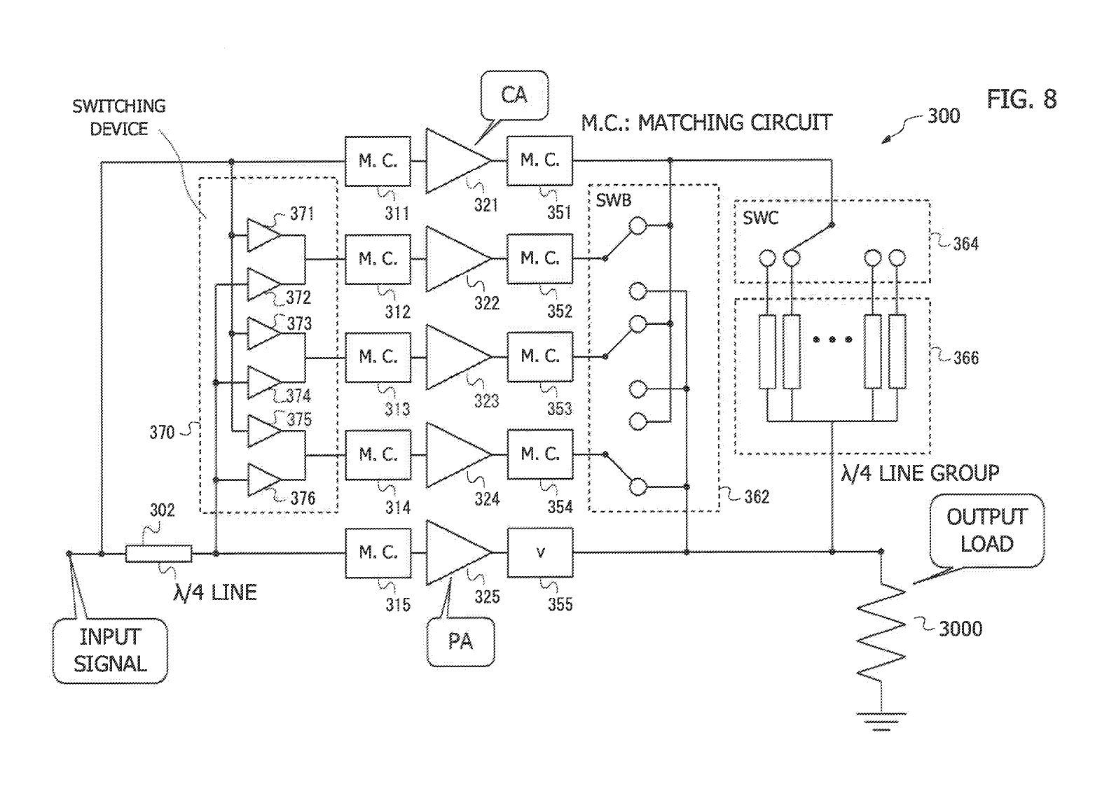

FIG. 8 is a diagram illustrating an example of the Doherty amplifier in the modified example 1-2. A Doherty amplifier 300 in FIG. 8 includes a λ/4 line 302, a switching device 370, a plurality of matching circuits 311-315 on the input side, a plurality of amplifiers 321-325, and a plurality of matching circuits 351-355 on the output side. The Doherty amplifier 300 further includes an output-side switch B 362, a switch C 364 and a λ/4 line group 366. Moreover, an output load 3000 is connected to the Doherty amplifier 300. The λ/4 line 302, the plurality of matching circuits 311-315 on the input side, the plurality of amplifiers 321-325, and the plurality of matching circuits 351-355 on the output side are the same as the corresponding components of the Doherty amplifier 100 or the Doherty amplifier 200. Further, the output-side switch B 362, the switch C 364 and the λ/4 line group 366 are the same as the corresponding components of the Doherty amplifier 100 or the Doherty amplifier 200.

The switching device 370 includes a plurality of amplifiers 371-376. The amplifiers 371-376 are, e.g., the FETs. Inputs of the amplifiers 371, 373 and 375 are connected to the CA-side inputs. Inputs of the amplifiers 372, 374 and 376 are connected to the PA-side inputs. Outputs of the amplifiers 371-376 are connected to the amplifiers 322-324 becoming the carrier amplifiers CA or the peaking amplifiers PA via the matching circuits 312-314. If the amplifiers 371-376 are the FETs, a status of operating as amplifying elements and a status of cutting off the signals inputted to the amplifiers 322-324 are switched over by changing the gate voltages or the drain voltages. If the amplifiers 371-376 are the transistors, the status of operating as amplifying elements and the status of cutting off the signals inputted to the amplifiers 322-324 are switched over by changing the base voltages or the collector voltages. For example, in the case of using the amplifiers 322-324 as the carrier amplifiers CA, the amplifiers 371, 373 and 375 are set in the operating status, while the amplifiers 372, 374 and 376 are set in the non-operating status. Further, e.g., the amplifier 371 and the amplifier 372 may also be set in the non-operating status.

The output-side switch B 362 operates together with the switching device 370. The output-side switch B 362 connects outputs of the matching circuits 352-354 to the switch C 364 or the output. The switching device 370 and the output-side switch B 362 are given by way of one example of the switching unit.

The Doherty amplifier 300 can take the multiple types of device size ratios CA:PA similarly to the Doherty amplifier 100 or the Doherty amplifier 200.

### Modified Example 1-3

A modified example 1-3 of the first embodiment will be described. The discussion herein will be focused on different points from the Doherty amplifier 100 or the Doherty amplifier 200 described above, while the explanations of the common points therebetween are omitted. In the modified example 1-2, a switching device is used as a substitute for the input-side switch A. The discussion herein will be focused on different points from the Doherty amplifier 100 or the Doherty amplifier 200 or the Doherty amplifier 300 described above, while the explanations of the common points therebetween are omitted. In the modified example 1-3, one λ/4 line is used in place of the switch C and the λ/4 line group.

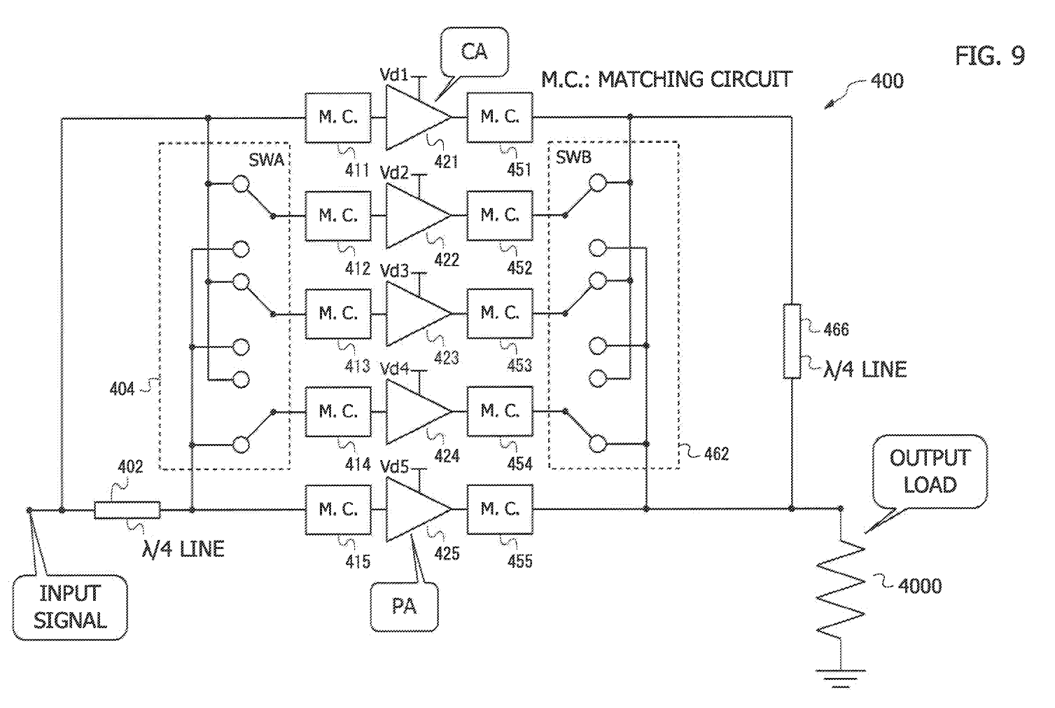

FIG. 9 is a diagram illustrating an example of the Doherty amplifier in the modified example 1-3. A Doherty amplifier 400 includes a λ/4 line 402, an input-side switch A 404, a plurality of matching circuits 411-415 on the input side, a plurality of amplifiers 421-425, and a plurality of matching circuits 451-455 on the output side. The Doherty amplifier 400 further includes an output-side switch B 462 and a λ/4 line 466. Moreover, an output load 4000 is connected to the Doherty amplifier 400.

The λ/4 line 402, the input-side switch A 404, the matching circuits 411-415, the plurality of amplifiers 421-425, and the output-side switch B 462 are the same as the corresponding components of the Doherty amplifier 100 or the Doherty amplifier 200 of the Doherty amplifier 300.

Drain voltages Vd1-Vd5 are applied to the amplifiers 421-425, respectively. For example, an unillustrated voltage setting circuit applies the drain voltages to the amplifiers 421-425. Herein, the drain voltage is changed, as given in the following formula, based on the ratio of the total of the device sizes of the carrier amplifiers CA to the total of the device sizes of the peaking amplifiers PA.

$$\frac{{V}_{CA}}{{V}_{PA}} = A \cdot \frac{m}{1 + m} \qquad [ Mathematical Expression 2 ]$$

V_{CA} represents a drain voltage of the amplifier operating as the carrier amplifier CA. V_{PA} denotes a drain voltage of the amplifier operating as the peaking amplifier PA. The symbol A stands for a constant. The symbol m represents a ratio of the total of the device sizes of the carrier amplifiers CA to the total of the device sizes of the peaking amplifiers PA. The drain voltage is thus changed, whereby the characteristic impedance of the λ/4 line 466 can be fixed.

The Doherty amplifier 400 may not prepare, unlike the Doherty amplifier 100 etc, the λ/4 line group containing the plurality of λ/4 lines having the impedances different from each other.

Further, the amplifiers 422-424 can be also set in the non-operating status by controlling the drain voltages applied to the amplifiers 422-424.

The voltage setting circuit can control the drain voltages applied to the amplifiers 421-425.

Herein, the FETs are assumed to be the amplifiers 421-425, however, the collector voltages may also be changed in the manner described above by use of the transistors as the amplifiers 421-425.

The configurations of the Doherty amplifier 100, the Doherty amplifier 200, the Doherty amplifier 300 and the Doherty amplifier 400 can be properly combined.

### Second Embodiment

Next, a second embodiment will be described. The second embodiment has the points common to the first embodiment. The discussion will therefore be focused on the different points therebetween, while the explanations of the common points are omitted.

(Example of Configuration)

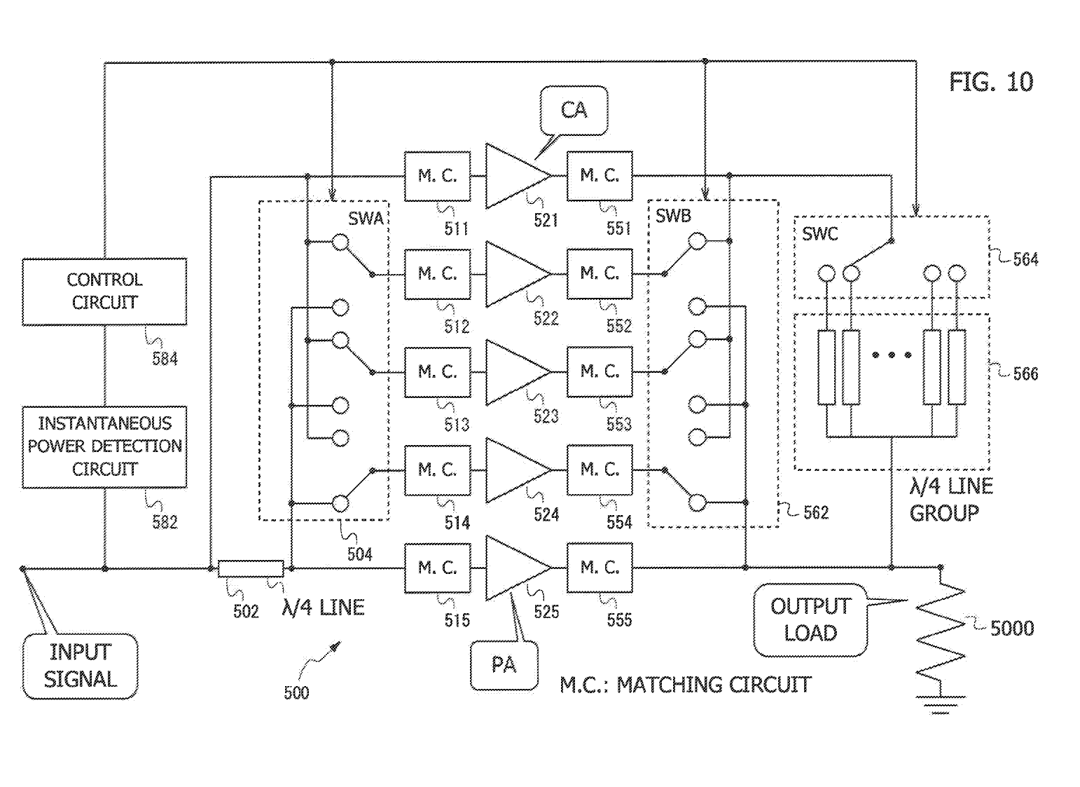

FIG. 10 is a diagram illustrating an example of the Doherty amplifier according to the second embodiment. A Doherty amplifier 500 includes a λ/4 line 502, an input-side switch A 504, a plurality of matching circuits 511-515 on the input side, a plurality of amplifiers 521-525, and a plurality of matching circuits 551-555 on the output side. The Doherty amplifier 500 further includes an output-side switch B 562, a switch C 564 and a λ/4 line group 566. The Doherty amplifier 500 includes an instantaneous power detection circuit 582 and a control circuit 584. Further, an output load 5000 is connected to the Doherty amplifier 500. The amplifier 521 operates as the carrier amplifier (CA). The amplifier 525 operates as the peaking amplifier (PA). The λ/4 line 502, the input-side switch A 504, the plurality of matching circuits 511-515 on the input side, the plurality of amplifiers 521-525, and the plurality of matching circuits 551-555 on the output side are the same as the corresponding components of the Doherty amplifier 100. The output-side switch B 562, the switch C 564 and the λ/4 line group 566 are the same as the corresponding components of the Doherty amplifier 100.

The Doherty amplifier 500 includes the same components as those of the Doherty amplifier 100 and may also include the same components as those of the Doherty amplifier 200 or the Doherty amplifier 300 in place of the same components as those of the Doherty amplifier 100.

The instantaneous power detection circuit 582 measures the instantaneous power of the input signal (RF signal). The instantaneous power detection circuit 582 notifies the control circuit 584 of a value of the measured instantaneous power. The instantaneous power detection circuit 582 is one example of a detection unit. The instantaneous power can be converted into the standardized voltage.

The instantaneous power detection circuit 582 standardizes, to “1”, a value obtained by converting the maximum power detected by the instantaneous power detection circuit 582 into a voltage.

The control circuit 584 switches over the input-side switch A 504, the output-side switch B 562 and the switch C 564 on the basis of the value of the instantaneous power of the input signal, which the instantaneous power detection circuit 582 has notified the control circuit 584 of. The control circuit 584 is one example of a control unit.

Herein, the Doherty amplifier 500 can take, similarly to the Doherty amplifier 100, the four types of CA-to-PA ratios such as 4:7, 5:6, 6:5 and 7:4. Namely, the relation between the standardized output voltage and the efficiency at each ratio that can be taken, is given as in FIG. 5. Herein, e.g., the instantaneous power detection circuit 582 detects the electric power corresponding to the instantaneous power (the standardized voltage) of 0.35, in which case the control circuit 584 determines the device size ratio CA:PA to be 4:7 on the basis of the relation between the standardized output voltage and the efficiency. The control circuit 584 switches over the input-side switch A 504 and the output-side switch B 562 so that CA:PA becomes 4:7. A graph having a peak (the maximum point) closest to the standardized output voltage of 0.35 is the graph of CA:PA=4:7 in FIG. 5. Hence, the Doherty amplifier 500 can amplify the signal having the instantaneous power of 0.35 at high efficiency by changing over CA:PA to 4:7. The control circuit 584 switches over the switch C 564 to select the λ/4 line corresponding to the case of CA:PA being 4:7 from the λ/4 line group 566. The control circuit 584 may select 4:7 as CA:PA exhibiting the highest efficiency under the standardized output voltage of 0.35 in FIG. 5.

Moreover, for instance, the instantaneous power detection circuit 582 detects the electric power corresponding to the instantaneous power (the standardized voltage) of 0.63, in which case the control circuit 584 determines CA:PA to be 7:4 on the basis of the relation between the standardized output voltage and the efficiency. The control circuit 584 switches over the input-side switch A 504 and the output-side switch B 562 so that the device size ratio CA:PA becomes 7:4. A graph having the peak closest to the standardized output voltage of 0.63 is the graph of CA:PA=7:4 in FIG. 5. Hence, the Doherty amplifier 500 can amplify the signal having the instantaneous power of 0.63 at the high efficiency by changing over CA:PA to 7:4. The control circuit 584 switches over the switch C 564 to select the λ/4 line corresponding to the case of CA:PA being 7:4 from the λ/4 line group 566. The control circuit 584 may select 7:4 as CA:PA exhibiting the highest efficiency under the standardized output voltage of 0.63 in FIG. 5.

The Doherty amplifier 500 includes the same configuration as the configuration of, e.g., the Doherty amplifier 200 in place of including the same configuration as that of the Doherty amplifier 100, whereby the more efficiency device size ratio CA:PA can be selected. For example, the Doherty amplifier 500, if including the same configuration as that of the Doherty amplifier 200, can select an optimal ratio from within the device size ratios CA:PA contained in FIG. 7.

### Operation and Effect of Second Embodiment

The instantaneous power detection circuit 582 of the Doherty amplifier 500 detects the instantaneous power of the input signal. The Doherty amplifier 500 converts the detected instantaneous power into the standardized voltage and selects the device size ratio CA:PA at which to exhibit the highest efficiency of the amplifier under the converted standardized voltage. The Doherty amplifier 500 switches over the input-side switch A 504 etc so as to become the selected device size ratio CA:PA.

The Doherty amplifier 500 can perform controlling in the high efficient status of the amplifier at all times by selecting the device size ratio CA:PA on the basis of the instantaneous power of the input signal.

### Modified Example 2-1

In the example of the Doherty amplifier 500 described above, the instantaneous power is detected by taking out the RF signal. Explained herein is an example of taking out a baseband digital signal etc instead of taking out the RF signal. The explanations of the portions common to those described above are omitted.

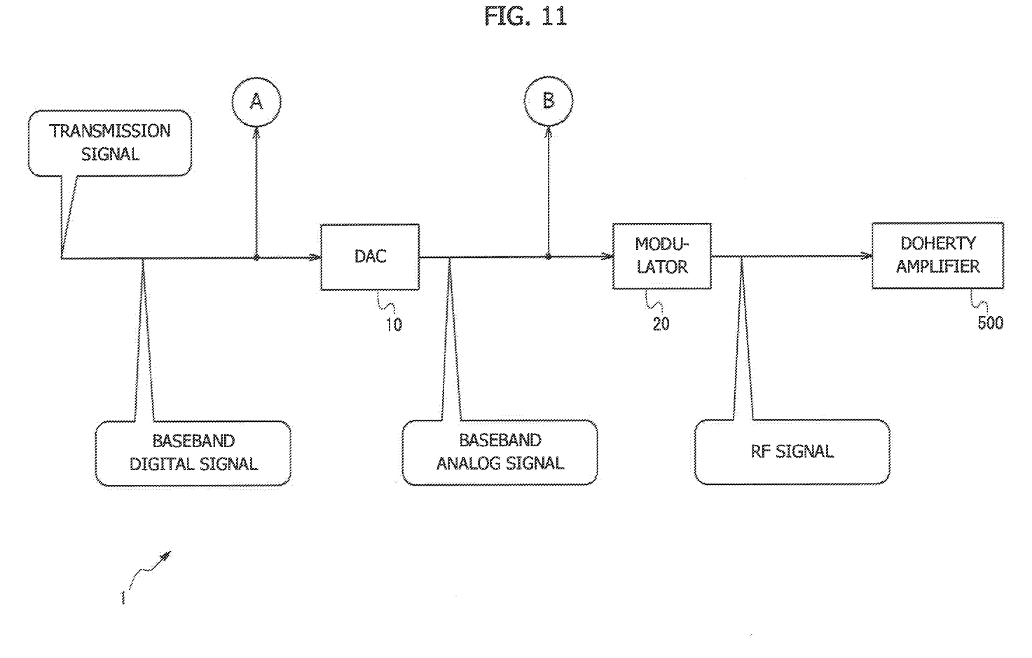

FIG. 11 is a diagram illustrating one example of a wireless device. A wireless device 1 in FIG. 11 includes a DAC (Digital to Analog Converter) 10, a modulator 20 and the Doherty amplifier 500. In the wireless device 1, the baseband digital signal as a transmission signal is inputted to the DAC 10. The DAC 10 converts the inputted baseband digital signal into a baseband analog signal. The modulator 20 converts the baseband analog signal converted as the analog signal into the RF signal (radio signal). The Doherty amplifier 500 amplifies the RF signal.

Herein, the instantaneous power detection circuit 582 of the Doherty amplifier 500 extracts the baseband digital signal ([A] in FIG. 11) and measures the instantaneous power of the signal. Alternatively, the instantaneous power detection circuit 582 of the Doherty amplifier 500 extracts the baseband analog signal ([B] in FIG. 11) and measures the instantaneous power of the signal. The instantaneous power detection circuit 582 notifies the control circuit 584 of a value of the measured instantaneous power.

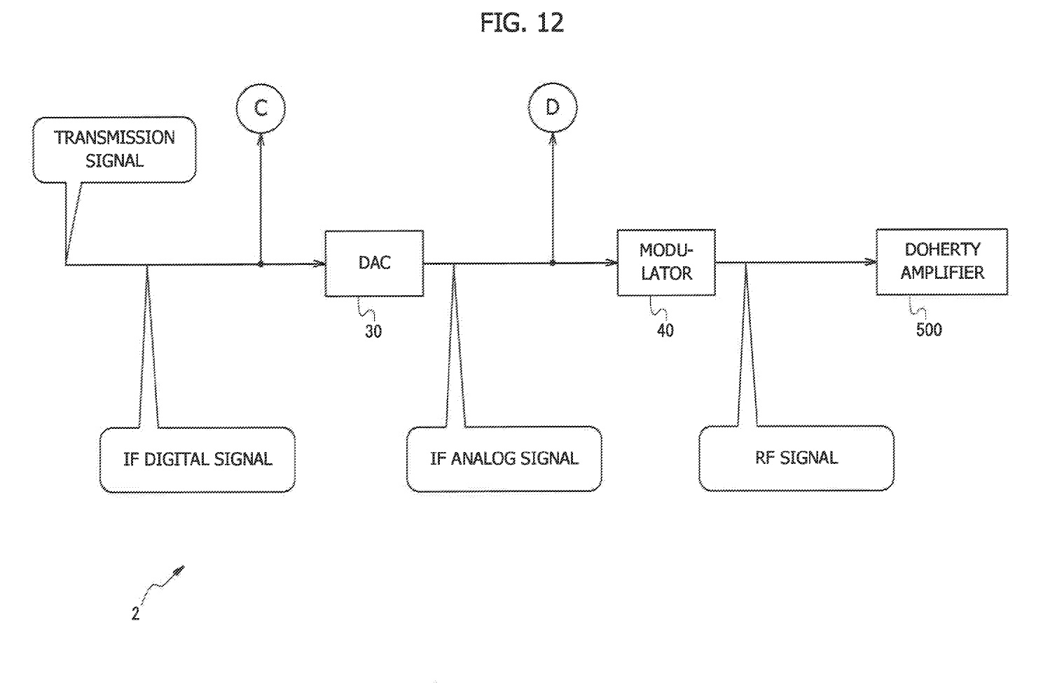

FIG. 12 is a diagram depicting another example of the wireless device. A wireless device 2 in FIG. 12 includes a DAC (Digital to Analog Converter) 30, a modulator 40 and the Doherty amplifier 500. In the wireless device 2, an IF (Intermediate Frequency) digital signal as a transmission signal is inputted to the DAC 30. The DAC 30 converts the inputted IF digital signal into an IF analog signal. The modulator 40 converts the IF analog signal converted as the analog signal into the RF signal (radio signal). The Doherty amplifier 500 amplifies the RF signal.

Herein, the instantaneous power detection circuit 582 of the Doherty amplifier 500 extracts the IF digital signal ([C] in FIG. 12) and measures the instantaneous power of the signal. Alternatively, the instantaneous power detection circuit 582 of the Doherty amplifier 500 extracts the IF analog signal ([D] in FIG. 12) and measures the instantaneous power of the signal. The instantaneous power detection circuit 582 notifies the control circuit 584 of a value of the measured instantaneous power.

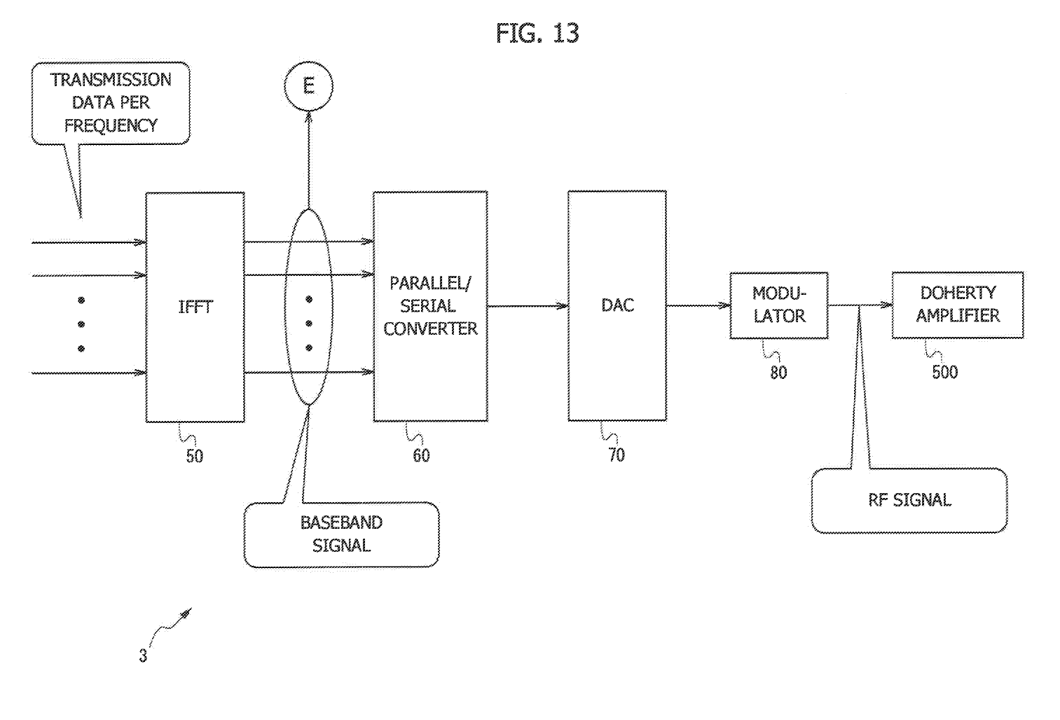

FIG. 13 is a diagram depicting still another example of the wireless device. A wireless device 3 in FIG. 13 includes an IFFT 50, a parallel/serial converter 60, a DAC 70, a modulator 80 and the Doherty amplifier 500. The wireless device 3 is a device that processes an OFDM (Orthogonal Frequency Division Multiplexing) signal. In the wireless device 3, transmission data on a per frequency basis is inputted to the IFFT 50. The IFFT 50 inverse-Fourier-transforms the inputted transmission on the per frequency basis, thereby converting the transmission data into a time-series parallel signal. The parallel/serial converter 60 converts the time-series parallel signal into a time-series serial signal. The time-series serial signal (digital signal) is inputted to the DAC (Digital to Analog Converter) 70. The DAC 70 converts the inputted digital signal into the analog signal. The modulator 80 converts the analog signal converted as the analog signal into the RF signal. The Doherty amplifier 500 amplifies the RF signal.

Herein, the instantaneous power detection circuit 582 of the Doherty amplifier 500 extracts the time-series parallel baseband digital signal ([E] in FIG. 13) and measures the instantaneous power of the signal. The instantaneous power detection circuit 582 notifies the control circuit 584 of a value of the measured instantaneous power.

In the wireless device according to the modified example 2-1, the instantaneous power can be measured by extracting the transmission signal at a much earlier stage. The wireless device in the modified example 2-1 measures the instantaneous power by extracting the transmission signal at the much earlier stage, thereby enabling a delay of the output signal to be restrained even when the process of the control circuit 584 is delayed.

### Third Embodiment

Next, a third embodiment will be described. The third embodiment has points common to the first embodiment and the second embodiment. Accordingly, the discussion herein will be focused on different points, while the explanations of the common points are omitted.

(Example of Configuration)

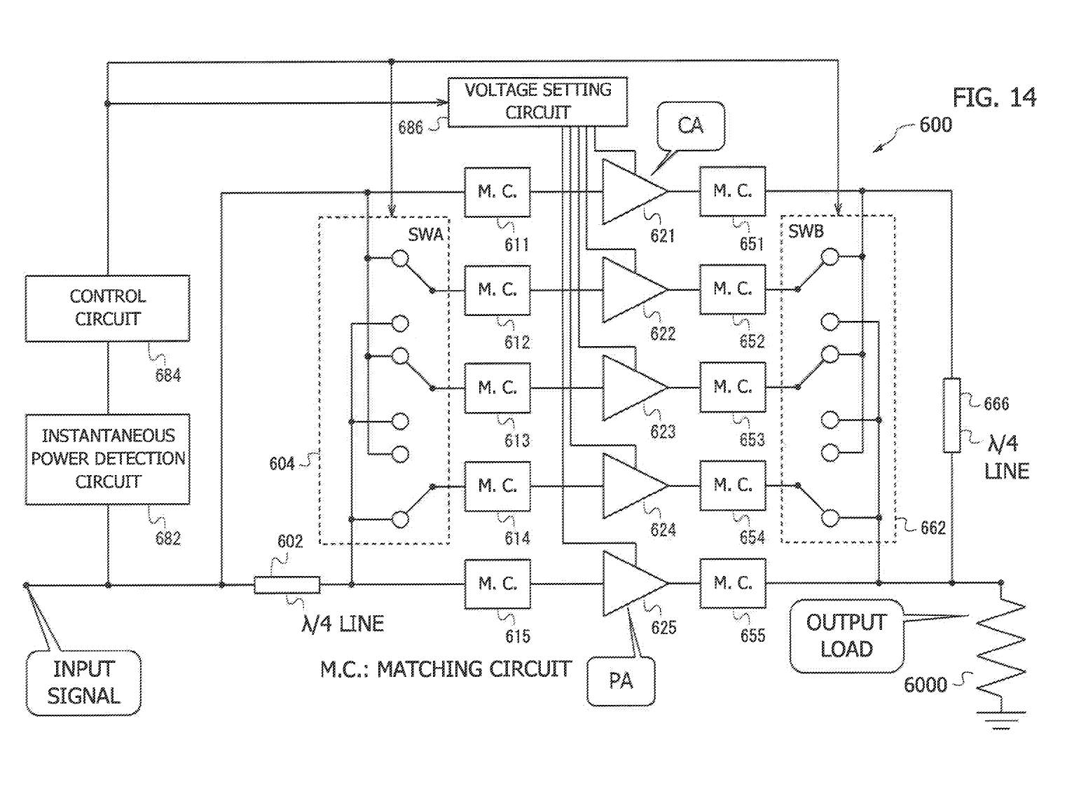

FIG. 14 is a diagram illustrating an example of the Doherty amplifier according to the third embodiment. A Doherty amplifier 600 includes a λ/4 line 602, an input-side switch A 604, a plurality of matching circuits 611-615 on the input side, a plurality of amplifiers 621-625, and a plurality of matching circuits 651-655 on the output side. The Doherty amplifier 600 further includes an output-side switch B 662 and a λ/4 line group 666. The Doherty amplifier 600 includes an instantaneous power detection circuit 682, a control circuit 684 and a voltage setting circuit 686. Further, an output load 6000 is connected to the Doherty amplifier 600. The amplifier 621 operates as the carrier amplifier (CA). The amplifier 625 operates as the peaking amplifier (PA). The λ/4 line 602, the input-side switch A 604, the plurality of matching circuits 611-615 on the input side, the plurality of amplifiers 621-625, and the plurality of matching circuits 651-655 on the output side are the same as the corresponding components of the Doherty amplifier 400. The output-side switch B 662 and the λ/4 line group 666 are the same as the corresponding components of the Doherty amplifier 400.

The instantaneous power detection circuit 682 measures the instantaneous power of the input signal. The instantaneous power detection circuit 682 notifies the control circuit 684 of a value of the measured instantaneous power.

The control circuit 684 switches over the input-side switch A 604, the output-side switch B 662 and the switch C 564 on the basis of the value of the instantaneous power of the input signal, which the instantaneous power detection circuit 682 has notified the control circuit 684 of. Furthermore, the control circuit 684 determines a voltage applied to each amplifier on the basis of the value, notified from the instantaneous power detection circuit 682, of the instantaneous power of the inputted signal, and gives an indication to the voltage setting circuit 686.

The voltage setting circuit 686 applies, to each amplifier, the voltage indicated from the control circuit 684.

The voltage setting circuit 686 has already applied to the drain voltage to each of the amplifiers 621-625. Herein, the drain voltage is changed based on the ratio of the total of the device sizes of the carrier amplifiers CA to the total of the device sizes of the peaking amplifiers PA as in the following formula.

$$\frac{{V}_{CA}}{{V}_{PA}} = A \cdot \frac{m}{1 + m} \qquad [ Mathematical Expression 3 ]$$

The symbol V_{CA} represents the drain voltage of the amplifier operating as the carrier amplifier CA. The symbol V_{PA} stands for the drain voltage of the amplifier operating as the peaking amplifier PA. The symbol A indicates the constant. The symbol m represents the ratio of the total of the device sizes of the carrier amplifiers CA to the total of the device sizes of the peaking amplifiers PA. The drain voltage is thus changed, whereby the characteristic impedance of the λ/4 line 666 can be fixed.

Moreover, the voltage setting circuit 686 can also set the amplifiers 622-624 in the non-operating status by controlling the drain voltages applied to the amplifiers 622-624.

Herein, the FETs are assumed to be the amplifiers 621-625, however, the collector voltages may also be changed in the manner described above by use of the transistors as the amplifiers 621-625.

The control circuit 684 can determine the device size ratio CA:PA in the same way as the control circuit 584 in the second embodiment does.

### Operation and Effect of Third Embodiment

In the Doherty amplifier 600, the voltage setting circuit 686 controls the voltages applied to the respective amplifiers. The Doherty amplifier 600 may not include the λ/4 line group containing the plurality of λ/4 lines having the impedances different from each other in a way that controls the voltages applied by the voltage setting circuit 686.

[Others]

In order for the Doherty amplifier to operate as such, the Doherty amplifier includes at least one peaking amplifier PA and at least one carrier amplifier CA. For example, the description of the first embodiment is that the amplifier 121 is used fixedly as the carrier amplifier CA, while the amplifier 125 is employed fixedly as the peaking amplifier PA. For instance, however, the switches SWA 104 may also be provided at the input of the matching circuit 111 connected to the input of the amplifier 121 and at the input of the matching circuit 115 connected to the input of the amplifier 125, and further the switches SWB 162 may also be provided at the output of the matching circuit 151 connected to the output of the amplifier 121 and at the output of the matching circuit 155 connected to the output of the amplifier 125. With this configuration, e.g., the Doherty amplifier 100 may be configured so that the amplifiers 121-125 are each set in any one of the PA status, the CA status and the non-operating status.

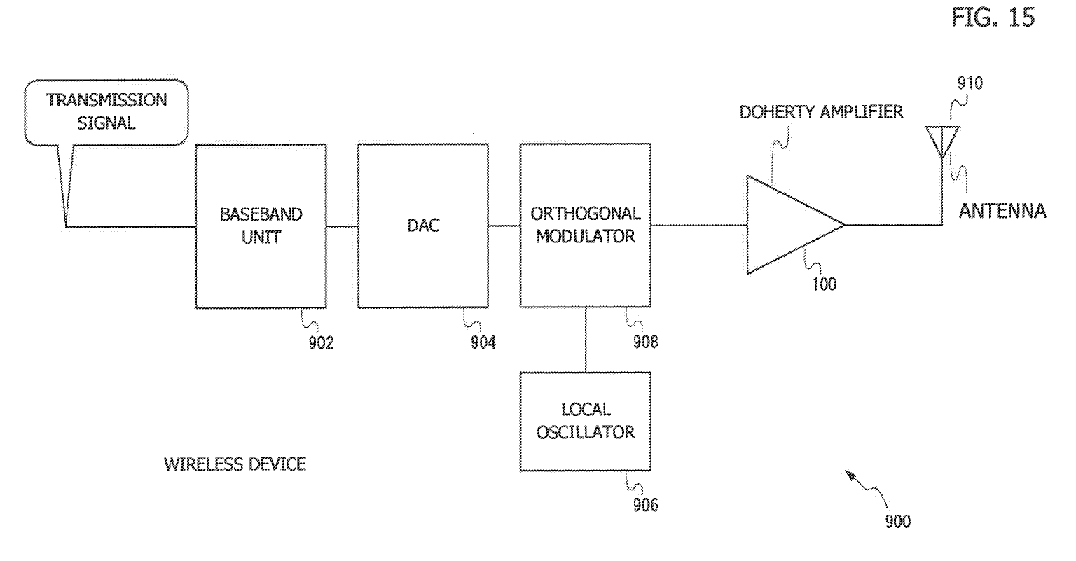

FIG. 15 is a diagram illustrating an example of the configuration of the wireless device including the Doherty amplifier. A wireless device 900 in FIG. 15 includes a baseband unit 902, a DAC 904, a local oscillator 906, an orthogonal modulator 908, a Doherty amplifier 100 and an antenna 910. The Doherty amplifier included in the wireless device 900 may be any one of the Doherty amplifiers other than the Doherty amplifier 100. Further, the wireless device including the Doherty amplifier described above is not limited to the example (configuration) in FIG. 15. The Doherty amplifier described above can operate as the amplifier included in each of other wireless devices. Moreover, the Doherty amplifier can operate as the amplifier included in each of devices exclusive of the wireless device.

The baseband unit 902 executes a process of encoding the transmission data, transmission sounds/voices, etc and allocates resources. The DAC 904 converts the signal encoded by the baseband unit into the analog signal. The local oscillator 906 generates an oscillation signal having a frequency of the radio signal transmitted from the wireless device 900. The orthogonal modulator 908 modulates the analog signal converted by the DAC 904 into the radio signal by use of the oscillation signal generated by the local oscillator 906.

The Doherty amplifier 100 amplifies the radio signal modulated by the orthogonal modulator 908. The modulated signal is output toward another wireless device from the antenna 910.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A Doherty amplifier comprising: a first amplifier, one or more second amplifiers and a third amplifier to receive inputs of high-frequency signals in parallel,
wherein the first amplifier serving as a carrier amplifier amplifies the high-frequency signal,
each of the second amplifiers serving as the carrier amplifiers or peaking amplifiers amplifies the high-frequency signal, and
the third amplifier serving as the peaking amplifier amplifies the high-frequency signal.

2. The Doherty amplifier according to claim 1, further comprising a switching unit to switch over each of the second amplifiers to the carrier amplifier or the peaking amplifier.

3. The Doherty amplifier according to claim 1, further comprising a switching unit to switch over each of the second amplifiers to any one of a carrier amplifier status, a peaking amplifier status and a non-operating status.

4. The Doherty amplifier according to claim 2, further comprising: a detection unit to detect instantaneous power of the high-frequency signal; and
a control unit to control the switching unit on the basis of a detection result of the detection unit.

5. The Doherty amplifier according to claim 1, further comprising a plurality of quarter-wave lines to have impedances different from each other,
wherein the first amplifier and the second amplifier operating as the carrier amplifier are connected to the quarter-wave line, in the plurality of quarter-wave lines, having an impedance that differs depending on a total of device sizes of the first amplifier and the second amplifier operating as the carrier amplifier and a total of device sizes of the second amplifier operating as the peaking amplifier and the third amplifier.

6. The Doherty amplifier according to claim 1, further comprising a quarter-wave line to be connected to the first amplifier and the second amplifier operating as the carrier amplifier,
wherein a first voltage is applied to the first amplifier and to the second amplifier operating as the carrier amplifier, and a second voltage is applied to the second amplifier operating as the peaking amplifier and to the third amplifier, and
the first voltage and the second voltage take values that differ depending on the total of the device sizes of the first amplifier and the second amplifier operating as the carrier amplifier and the total of the device sizes of the second amplifier operating as the peaking amplifier and the third amplifier.
